(19) United States
(12) Patent Application Publication
(10) Pub. No.: US 2015/0214405 A1
(43) Pub. Date: Jul. 30, 2015

(54) METHODS OF MAKING BARRIER ASSEMBLIES

(71) Applicant: 3M INNOVATIVE PROPERTIES COMPANY, SAINT PAUL, MN (US)

(72) Inventors: Alan K. Nachtigal, Minneapolis, MN (US); Andrew T. Ruff, Mendota Heights, MN (US); Christopher S. Lyons, Saint Paul, MN (US); Guy D. Joly, Shoreview, MN (US); Joseph C. Spagnola, Woodbury, MN (US); Mark D. Weigel, Hugo, MN (US); Michael D. Delmore, Grant, MN (US); Samuel Kidane, Saint Paul, MN (US); Thomas P. Klun, Lakeland, MN (US)

(21) Appl. No.: 14/421,035

(22) PCT Filed: Aug. 15, 2013
(86) PCT No.: PCT/US13/55036

§ 371 Date: Feb. 11, 2015

Related U.S. Application Data
(60) Provisional application No. 61/746,356, filed on Dec. 27, 2012.
(60) Provisional application No. 61/683,824, filed on Aug. 16, 2012.

(51) Int. Cl. H01L 31/048; B32B 27/08; B32B 27/36; H01L 51/52

(52) U.S. Cl. CPC H01L 31/048; H01L 51/524; B32B 27/08; B32B 27/36; B32B 2255/20; B32B 2255/26; B32B 2307/71

(57) ABSTRACT

The present disclosure generally relates to methods of forming barrier assemblies. Some embodiments include application of an adhesive layer and/or a topsheet to protect the exposed uppermost layer of the barrier stack during roll-to-roll processing. Some embodiments include application of an adhesive layer and/or a topsheet before the exposed, uppermost layer of the barrier film contacts a solid surface or processing roll. Inclusion of an adhesive layer and/or a topsheet protects the oxide layer during processing, which creates an excellent barrier assembly that can be manufactured using roll-to-roll processing.

### RELATED APPLICATION

The present application claims priority to and benefit of U.S. Patent Application No. 61/683,824, filed Aug. 16, 2012 and U.S. Patent Application No. 61/746,356, filed Dec. 27, 2012.

### TECHNICAL FIELD

The present disclosure generally relates to methods of making barrier assemblies and the barrier assemblies made using these methods.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels. As a result of these concerns, countries worldwide have been establishing initiatives to develop both large-scale and small-scale renewable energy resources.

One of the promising energy resources today is sunlight. Globally, millions of households currently obtain power from solar energy generation. The rising demand for solar power has been accompanied by a rising demand for devices and materials capable of fulfilling the requirements for these applications. Photovoltaic cells are a fast-growing segment of solar power generation.

Two specific types of photovoltaic cells—organic photovoltaic devices (OPVs) and thin film solar cells (e.g., copper indium gallium di-selenide (CIGS)) require protection from water vapor and need to be durable (e.g., to ultra-violet (UV) light) in outdoor environments. Glass is typically used for such solar devices because glass is a very good barrier to water vapor, is optically transparent, and is stable to UV light. However, glass is heavy, brittle, difficult to make flexible, and difficult to handle. Transparent flexible encapsulating materials are being developed to replace glass. Preferably, these materials have glass-like barrier properties and UV stability. These flexible barrier films are desirable for electronic devices whose components are sensitive to the ingress of water vapor, such as, for example, flexible thin film and organic photovoltaic solar cells and organic light emitting diodes (OLEDs).

Some exemplary barrier films of this general type include multilayer stacks of polymers and oxides deposited on flexible plastic films to make high barrier films resistant to moisture permeation. Examples of these barrier films are described in U.S. Pat. Nos. 5,440,446; 5,877,895; 6,010,751; U.S. Pat. App. Pub. No. 2003/0029493; and 66737US002, all of which are incorporated herein by reference as if fully set forth herein.

### SUMMARY

The inventors of the present application recognized that under certain conditions multilayer stacks of polymers and oxides may suffer degradation in adhesion performance after extended exposure to moisture, possibly causing these high barrier stacks to delaminate at the oxide-polymer interface. For example, the inventors of the present disclosure recognized that in some embodiments, the second polymer layer suffers from low adhesion when exposed to damp heat during use or testing. The inventors thus realized that in some embodiments, it may be preferable not to include the second polymer layer in the barrier stack.

The inventors of the present disclosure also recognized that roll-to-roll processing of barrier films is a preferred manufacturing method that provides efficiency and superior products. However, roll-to-roll processing of barrier films has some challenges. One such challenge is that this manufacturing method involves contacting the barrier stack with a processing roll (e.g., any type of processing roll, including, for example, a web handling roll, an idler roll, a spreader roll, a capstan roll, a tension roll, etc.). The uppermost layer (in some embodiments, an oxide layer or a polymer layer) of the barrier stack is exposed (i.e., not covered by another layer) during processing and is thus susceptible to deformation or degradation during processing. Such deformation or degradation can negatively affect the performance characteristics of the final barrier stack or film. In one specific example, the optional second polymer layer is not included and the oxide layer is the uppermost (and thus exposed) layer in the barrier stack. Because the oxide layer is very thin, it can be deformed or degraded when it contacts the processing roll, causing the performance of the final barrier stack to suffer.

One method of addressing the above-identified concerns is to place a temporary protective layer on the uppermost layer during roll-to-roll processing. The temporary layer is present during the processing steps that involve contacting the exposed, uppermost layer with a processing roll but is removed before the final barrier stack is formed (e.g., by addition of layers 20 and 22). This method is described in greater detail in U.S. Patent Application No. 61/683,824 (incorporated herein by reference in its entirety).

A second method of addressing the above-identified concerns involves placing the adhesive and/or topsheet layers on the exposed, uppermost layer during processing and before the uppermost layer contacts any type of processing roll or other solid processing surface. The adhesive and/or topsheet layers protect the exposed uppermost layer during processing, which creates an improved barrier assembly that can be manufactured with roll-to-roll processing. Inclusion of the adhesive layer and/or topsheet layer during processing reduces defect formation in the uppermost layer and thus provides an improved end product barrier stack or film.

Some embodiments of the present disclosure relate to a method of forming a barrier assembly involving providing a substrate; applying a polymeric material adjacent to the substrate to form a polymer layer; applying an oxide-containing material adjacent to the polymer layer to form an oxide layer; applying at least one of an adhesive material and a topsheet layer to an uppermost layer to form a multilayer film; wherein the uppermost layer is either the oxide layer or the polymer layer; and wherein the adhesive material or topsheet layer are applied to the uppermost layer before the uppermost layer contacts a processing roll.

Some embodiments of the present disclosure relate to a method of forming a barrier assembly involving providing a substrate; applying a polymeric material adjacent to the substrate to form a polymer layer; applying an oxide-containing material adjacent to the polymer layer to form an oxide layer; applying at least one of an adhesive material and a topsheet layer to and uppermost layer before the uppermost layer contacts any solid surface; and wherein the uppermost surface is one of the oxide layer or the polymer layer.

In some embodiments, the adhesive material includes a UV absorber. In some embodiments, the adhesive is a pressure sensitive adhesive.

In some embodiments, the steps of applying a polymeric material and/or applying an oxide-containing material are repeated sequentially numerous times to form a barrier assembly having numerous alternating polymer layers and/or oxide layers. In some embodiments, the barrier assembly is flexible and transmissive to visible and infrared light.

In some embodiments, the method further comprises forming a continuous roll of barrier assembly. Some embodiments are optical devices including a barrier assembly as described herein. Some embodiments are photovoltaic modules including a barrier assembly as described herein.

Other features and advantages of the present application are described or set forth in the following detailed specification that is to be considered together with the accompanying drawings.

### BRIEF DESCRIPTION OF DRAWING

The disclosure may be more completely understood in consideration of the following detailed description of various embodiments of the disclosure in connection with the accompanying drawings, in which:

FIG. 1 is a schematic drawing showing an exemplary barrier film on a processing roll.

### DETAILED DESCRIPTION

In the following detailed description, reference may be made to the accompanying drawing that forms a part hereof and in which is shown by way of illustration one exemplary specific embodiment. It is to be understood that other embodiments are contemplated and may be made without departing from the scope or spirit of the present disclosure.

The present disclosure generally relates to methods of forming a barrier assembly or film that involve placing an adhesive layer and/or topsheet on the exposed, uppermost layer of the barrier stack during processing and before the uppermost layer contacts any type of processing roll or other solid processing surface. The adhesive layer and/or topsheet protects the exposed uppermost layer during processing, which creates a barrier assembly that can be manufactured using roll-to-roll processing. In some embodiments, the uppermost layer is an oxide layer. In some embodiments, the uppermost layer is a polymer layer.

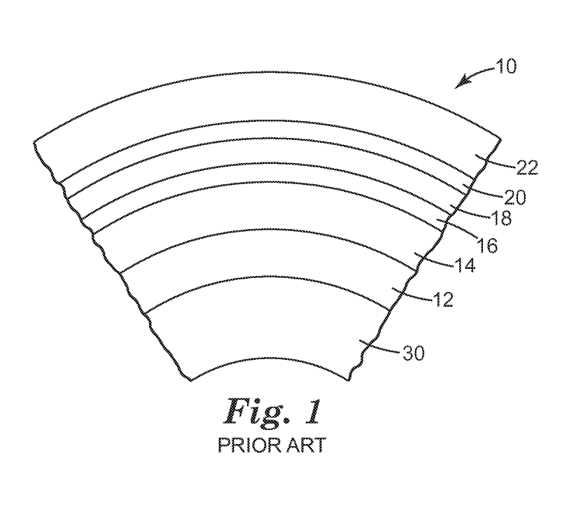

One exemplary barrier assembly 10 is shown in FIG. 1. Barrier assembly 10 includes a substrate 12; a first polymer layer 14 (e.g., an acrylate layer); an oxide layer 16; a second polymer layer (e.g., an acrylate layer) 18; an adhesive layer 20; and a topsheet layer 22. Substrate 12 of barrier assembly 10 is shown on a processing roll 30. In the exemplary barrier stack shown in FIG. 1, the uppermost layer is second polymer layer 18. However, the uppermost layer can be any layer and is typically a polymeric or oxide layer. The uppermost layer is protected by adhesive layer 20 and topsheet layer 22 during processing.

At least some embodiments of the barrier assemblies described herein are transmissive to visible and infrared light. The term “transmissive to visible and infrared light” as used herein means having an average transmission over the visible and infrared portion of the spectrum of at least about 75% (in some embodiments at least about 80, 85, 90, 92, 95, 97, or 98%) measured along the normal axis. In some embodiments, the barrier assembly has an average transmission over a range of 400 nm to 1400 nm of at least about 75% (in some embodiments at least about 80, 85, 90, 92, 95, 97, or 98%). Typically, visible and infrared light-transmissive assemblies do not interfere with absorption of visible and infrared light, for example, by photovoltaic cells. In some embodiments, the visible and infrared light-transmissive assembly has an average transmission over a range of wavelengths of light that are useful to a photovoltaic cell of at least about 75% (in some embodiments at least about 80, 85, 90, 92, 95, 97, or 98%). The layers in the barrier assembly can be selected based on refractive index and thickness to enhance transmission to visible and infrared light.

In at least some embodiments, the barrier assemblies described herein are flexible. The term “flexible” as used herein refers to being capable of being formed into a roll. In some embodiments, the barrier assembly is capable of being bent around a roll core with a radius of curvature of up to 7.6 centimeters (cm) (3 inches), in some embodiments up to 6.4 cm (2.5 inches), 5 cm (2 inches), 3.8 cm (1.5 inch), or 2.5 cm (1 inch). In some embodiments, the barrier assembly can be bent around a radius of curvature of at least 0.635 cm (¼ inch), 1.3 cm (½ inch) or 1.9 cm (¾ inch).

Barrier assemblies according to the present disclosure generally do not exhibit delamination or curl that can arise from thermal stresses or shrinkage in a multilayer structure. Herein, curl is measured using a curl gauge described in “Measurement of Web Curl” by Ronald P. Swanson presented in the 2006 AWEB conference proceedings (Association of Industrial Metallizers, Coaters and Laminators, Applied Web Handling Conference Proceedings, 2006). According to this method, curl can be measured to the resolution of 0.25 m⁻¹ curvature. In some embodiments, barrier assemblies according to the present disclosure exhibit curls of up to 7, 6, 5, 4, or 3 m⁻¹. From solid mechanics, the curvature of a beam is known to be proportional to the bending moment applied to it. The magnitude of bending stress in turn is known to be proportional to the bending moment. From these relations the curl of a sample can be used to compare the residual stress in relative terms.

Some embodiments of barrier assemblies of the type described and claimed herein can include additional alternating layers of polymer and/or oxide. Exemplary materials and construction methods for barrier assembly 10 are identified in U.S. Pat. Nos. 5,440,446; 5,877,895; 6,010,751; U.S. Pat. App. Pub. No. 2003/0029493; 69821US002, and 66737US002 (all of which are herein incorporated by reference as if fully set forth herein) and in the Examples of the present disclosure. As used herein, the term “polymeric” will be understood to include organic homopolymers and copolymers, as well as polymers or copolymers that may be formed in a miscible blend, for example, by co-extrusion or by reaction, including transesterification. The terms “polymer” and “copolymer” include both random and block copolymers.

In one embodiment of the present application, an adhesive material and/or a topsheet is applied to the exposed, uppermost layer during roll-to-roll processing. In some embodiments, the uppermost layer is an oxide layer. In some embodiments, the uppermost layer is a polymer layer. In some embodiments, nipping is used to adhere the topsheet and/or adhesive layer to the barrier stack. The inclusion of an adhesive material and/or a topsheet reduces defect formation in the uppermost layer during manufacturing because the adhesive material and/or a topsheet (alone or in combination) protect the uppermost layer from damage during vacuum web handling and subsequent process steps.

Any adhesive may be used in the methods described herein. In some embodiments, the adhesive material is a pressure sensitive adhesive. In some embodiments, stabilizers are added to the pressure sensitive adhesive. Examples of such stabilizers include at least one of ultra violet absorbers (UVA) (e.g., red shifted UV absorbers), hindered amine light stabilizers (HALS), or anti-oxidants. Other exemplary embodiments include those listed in U.S. Patent Application Publication No. 2012/0003448 (Weigel et al), incorporated by reference herein in its entirety. In embodiments where only an adhesive layer is deposited on or applied to the oxide layer, the adhesive layer preferably includes a release liner.

Deposition of the adhesive material can be accomplished in any desired way. For example, the adhesive material can be applied using conventional coating methods such as roll coating (e.g., gravure roll coating) or spray coating (e.g., electrostatic spray coating). In some embodiments, the adhesive can be crosslinked. In some embodiments, the adhesive can be formed by applying a layer in solvent and drying the thus-applied layer to remove the solvent. Additionally, the adhesive material can be adhered or attached to the oxide layer by placing the film directly adjacent to the oxide layer. In some embodiments, any of the methods described above are done as an in-line process. In some embodiments, the adhesive is coated between two liners, one of which is removed and the exposed adhesive surface is applied to (or laminated to) a topsheet. The entire resulting adhesive/topsheet construction can then be applied to the uppermost layer of the barrier stack (e.g., in a vacuum chamber).

Any topsheet material can be used in the embodiments of the present application. Useful materials that can form the topsheet include polyacrylates, polyesters, polycarbonates, polyethers, polyimides, polyolefins, fluoropolymers, and combinations thereof. Exemplary materials for use in the topsheet include those listed in U.S. Patent Application Publication No. 2012/0003448 (Weigel et al), incorporated by reference herein in its entirety.

In some embodiments, some of the topsheet blocks visible light (e.g., 380 to 750 nm) from reaching the barrier stack. In some embodiments, some of the topsheet is opaque. For the purpose of the present disclosure, a portion of the topsheet is opaque if the opaque portion of the barrier stack has a maximum of 20% transmission at any wavelength between 380 and 450 nm. In some embodiments, the opaque portion has less than 15% transmission of light at any wavelength between 380 and 450 nm. In some embodiments, the opaque portion has less than 10% transmission of light at any wavelength between 380 and 450 nm. In some embodiments, the opaque portion has less than 5% transmission of light at any wavelength between 380 and 450 nm. In some embodiments, the opaque portion has less than 2% transmission of light at any wavelength between 380 and 450 nm. In some embodiments, the opaque portion has less than 0.2% transmission of light at any wavelength between 380 and 450 nm. The opaque portion may form a pattern including, for example, those patterns described in U.S. Patent Application Nos. 61/605,525 and 61/515,073, incorporated herein by reference in their entirety. Exemplary materials that can be used to create an opaque portion include, for example, inks and tapes. Where the opaque region includes an opaque tape, the tape may be in any orientation within the multilayer film.

In some embodiments, stabilizers are added to the topsheet to improve its resistance to UV light. Examples of such stabilizers include at least one of ultra violet absorbers (UVA) (e.g., red shifted UV absorbers), hindered amine light stabilizers (HALS), or anti-oxidants. Other exemplary include those listed in U.S. Patent Application Publication No. 2012/0003448 (Weigel et al), incorporated by reference herein in its entirety.

In some embodiments, the topsheet includes an adhesive layer. In some embodiments, that adhesive layer is a pressure sensitive adhesive.

Application of the topsheet to the adhesive material or oxide layer can be accomplished in any desired way. Typically, the topsheet is adhered or attached to the adhesive or oxide layer by placing the film directly adjacent to the adhesive or oxide layer. However, any of the application methods described above with respect to adhesives can be employed for the topsheet.

At least some embodiments of the barrier films or assemblies made using the processes described herein have high optical transmission of 85% or higher. At least some embodiments of the barrier films or assemblies made using the processes described herein have low water vapor transmission rates of 0.005 g/m2-day or lower at 50° C. and 100% RH. Additionally, at least some embodiments of the barrier films or assemblies made using the processes described herein are highly durable and maintain interlayer adhesion when exposed to external stresses such as, for example, UV light, thermal cycling, and moisture ingress.

In some embodiments, the barrier film can be fabricated by deposition of the various layers onto the substrate in a roll-to-roll vacuum chamber described in or similar to the system described in U.S. Pat. No. 5,440,446 (Shaw et al.) and U.S. Pat. No. 7,018,713 (Padiyath, et al.), both of which are incorporated by reference herein in their entirety.

Some advantages of the methods of the present disclosure include, for example, enablement of low-cost, continuous, roll-to-roll processing. Additionally, the application of at least one of an adhesive layer and/or a topsheet permits the creation of a barrier assembly with fewer interfaces because it eliminates the temporary protective layer and the second polymer layer from the final barrier assembly. Fewer interfaces may lead to decreased risk of adhesive failure between interfaces (e.g., between the oxide and polymer layers). In instances where the prior art protective layer was susceptible to adhesion loss, the removal of this protective layer from the final construction may result in a barrier assembly with increased weatherability and longevity. The presence of a temporary protective layer during processing reduces the incidence of particulate contamination during processing/manufacturing. Also, the presence of a temporary protective layer during processing protects the exposed, uppermost layer from damage or contamination during processing and handling.

In one embodiment, the barrier assembly of the present disclosure is used in a photovoltaic module. The photovoltaic module includes a backsheet; a solar cell; and a barrier assembly made according to the method of any of the preceding claims.

In some embodiments, the barrier assembly of the present disclosure is used in an optical device, optical display device, or solid state lighting device. One exemplary optical device is an organic light emitting diode (OLED).

### EXAMPLES

### Example 1

Barrier films were prepared by covering a polyetheylene teraphthalate (PET) substrate film (obtained from E. I. DuPont de Nemours, Wilmington, Del., under the trade name “XST 6642”) with a stack of a base polymer layer and an inorganic silicon aluminum oxide (SiAlOx) barrier layer on a vacuum coater similar to the coater described in U.S. Pat. No. 5,440,446 (Shaw et al.) and U.S. Pat. No. 7,018,713 (Padiyath, et al), both of which are incorporated herein by reference. The individual layers were formed as follows:

Layer 1 (polymer layer): a 310 meter long roll of 0.127 mm thick×366 mm wide PET film was loaded into a roll-to-roll vacuum processing chamber. The chamber was pumped down to a pressure of 2×10-5 Torr. A web speed of 4.9 meter/min was held while maintaining the backside of the PET film in contact with a coating drum chilled to −10° C. With the backside in contact with the drum, the film frontside surface was treated with a nitrogen plasma at 0.02 kW of plasma power. The film frontside surface was then coated with tricyclodecane dimethanol diacrylate monomer (obtained under the trade designation “SR-833S”, from Sartomer USA, Exton, Pa.). The monomer was degassed under vacuum to a pressure of 20 mTorr prior to coating, loaded into a syringe pump, and pumped at a flow rate of 1.33 mL/min through an ultrasonic atomizer operating at a frequency of 60 kHz into a heated vaporization chamber maintained at 260° C. The resulting monomer vapor stream condensed onto the film surface and was electron beam crosslinked using a multi-filament electron-beam cure gun operating at 7.0 kV and 4 mA to form a 720 nm thick base polymer layer.

Layer 2 (inorganic layer): immediately after the base polymer layer deposition and with the backside of the PET film still in contact with the drum, a SiAlOx layer was sputter-deposited atop a 30 m length of the base polymer layer. Two alternating current (AC) power supplies were used to control two pairs of cathodes; with each cathode housing two 90% Si/10% Al sputtering targets (obtained from Materion Corporation, Mayfield Heights, Ohio). During sputter deposition, the voltage signal from each power supply was used as an input for a proportional-integral-differential control loop to maintain a predetermined oxygen flow to each cathode. The AC power supplies sputtered the 90% Si/10% Al targets using 5000 watts of power, with a gas mixture containing 850 standard cubic centimeter per minute (sccm) argon and 92 sccm oxygen at a sputter pressure of 3.2 millitorr. This provided a 26 nm thick SiAlOx layer deposited atop the base polymer layer of Layer 1.

The two-layer stack was then covered with a 0.05 mm thick pressure sensitive adhesive (PSA) (commercially available from 3M Company, St. Paul, Minn. under the trade designation “3M OPTICALLY CLEAR ADHESIVE 8172P”), and a 0.05 mm thick ETFE (commercially available from available from St. Gobain Performance Plastics, Wayne, N.J. under the trade designation “NORTON ETFE”).

Spectral transmission (Tvis) of the barrier films was measured using a spectrometer (model “LAMBDA 900”, commercially available from PerkinElmer, Waltham, Mass.). Spectral transmission is reported as average percent transmission (Tvis) between 400 nm and 700 nm at a 0° angle of incidence.

Water vapor transmission rate (WVTR) of the barrier film of Example 1 were measured in accordance with the procedure outlined in ASTM F-1249-06, “Standard Test Method for Water Vapor Transmission Rate Through Plastic Film and Sheeting Using a Modulated Infrared Sensor” using a MOCON PERMATRAN-W Model 700 WVTR testing system (obtained from MOCON, Inc, Minneapolis, Minn.). Temperature of about 50° C. and relative humidity (RH) of about 100% were used and WVTR is expressed in grams per square meter per day (g/m²/day). The lowest detection limit of the testing system was 0.005 g/m²/day.

Preparation of an Exemplary Representative Solar Module Including the Barrier Layer of Example 1

An exemplary representative solar module including the barrier layer of Example 1 (“Representative Module”) was prepared by placing the polyethylene terephthalate (PET) side of the Example 1 barrier film on the polytetrafluoroethylene (PTFE) side of a 0.14 mm (0.0056 in) thick 21.6 cm by 14 cm PTFE-coated aluminum foil (obtained under the trade designation “8656K61”, from McMaster-Carr, Santa Fe Springs, Calif.). The PTFE-coated aluminum foil was 1.27 cm smaller than the barrier film in each dimension, thus leaving a portion of the PET exposed. A 13 mm (0.5 in) wide desiccated edge tape (obtained under the trade designation “SOLARGAIN EDGE TAPE SET LP01” from Truseal Technologies Inc., Solon, Ohio) was placed around the perimeter of the PTFE-coated aluminum foil to secure the Example 1 barrier film atop the PTFE layer. Strips of cobalt chloride indicator paper were placed between the PTFE-coated foil and the barrier film to monitor moisture ingress. A 0.38 cm (0.015 in) thick encapsulant film (obtained under the trade designation “JURASOL” from JuraFilms, Downer Grove, Ill.) was placed on the aluminum side of the PTFE-coated aluminum foil. The PET layer of a second laminated barrier sheet was disposed over the encapsulant film, to form a laminate construction. The construction was vacuum laminated at 150° C. for 12 min.

Initial T-peel adhesion was tested as follows. The barrier film of the Representative Module was removed from the laminate construction by cutting it away from the polytetrafluoroethylene (PTFE) layer. The barrier films were then cut into 1.0 in wide (2.54 cm) sections. These sections were placed in a tensile strength tester (obtained under the trade designation “INISIGHT 2 SL” with Testworks 4 software from MTS, Eden Prairie, Minn.), following the procedure outlined in ASTM D 1876-08 “Standard Test Method for Peel Resistance of Adhesives (T-Peel Test).” A peel speed of 254 mm/min (10 inches/min) was used. Adhesion is reported in Table 1 below in Newton per centimeter (N/cm) as the average of four peel measurements between 13 to 151 mm (0.5 and 5.95 inches) of extension.

The Representative Module was then aged for 500 hours as follows. The Representative Module was placed in an environmental chamber (model “SE-1000-3,” obtained from Thermotron Industries, Holland, Mich.) set to a temperature of about 85° C. and relative humidity of about 85%, for 500 hours. The cobalt chloride indicator paper placed in the Representative Module remained blue (i.e., no water ingress was detected) after 500 hours.

The aged Representative Module was T-peel adhesion tested using the method described above. Adhesion is reported in Table 1 below in Newton per centimeter (N/cm) as the average of four peel measurements between 13 to 151 mm (0.5 and 5.95 inches) of extension.

TABLE 1
Performance Characteristics

| | Barrier Film 1 | | Representative Module | |
|---|---|---|---|---|
| | Spectral | Initial | T-Peel Adhesion (N/cm) | |
| | Transmission | WVTR | Initial | 500 |
| | (%) | (g/m²/day) | (0 hours) | hours |
| Example 1 | 88 | <0.005 | 12.4 | 11.1 |

All references mentioned herein are incorporated by reference.

As used herein, the words “on” and “adjacent” cover both a layer being directly on and indirectly on something, with other layers possibly being located therebetween.

As used herein, the terms “major surface” and “major surfaces” refer to the surface(s) with the largest surface area on a three-dimensional shape having three sets of opposing surfaces.

Unless otherwise indicated, all numbers expressing feature sizes, amounts, and physical properties used in the present disclosure and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise.

As used in this disclosure and the appended claims, the term “or” is generally employed in its sense including “and/or” unless the content clearly dictates otherwise.

The phrases “at least one of” and “comprises at least one of” followed by a list refers to any one of the items in the list and any combination of two or more items in the list. All numerical ranges are inclusive of their endpoints and non-integral values between the endpoints unless otherwise stated.

Various embodiments and implementation of the present disclosure are disclosed. The disclosed embodiments are presented for purposes of illustration and not limitation. The implementations described above and other implementations are within the scope of the following claims. One skilled in the art will appreciate that the present disclosure can be practiced with embodiments and implementations other than those disclosed. Those having skill in the art will appreciate that many changes may be made to the details of the above-described embodiments and implementations without departing from the underlying principles thereof. It should be understood that this invention is not intended to be unduly limited by the illustrative embodiments and examples set forth herein and that such examples and embodiments are presented by way of example only with the scope of the invention intended to be limited only by the claims set forth herein as follows. Further, various modifications and alterations of the present invention will become apparent to those skilled in the art without departing from the spirit and scope of the present disclosure. The scope of the present application should, therefore, be determined only by the following claims.

1. A method of forming a barrier assembly, comprising:
providing a substrate;
applying a polymeric material adjacent to the substrate to form a polymer layer;
applying an oxide-containing material adjacent to the polymer layer to form an oxide layer;
applying at least one of an adhesive material and a topsheet layer to an uppermost layer to form a multilayer film;
wherein the uppermost layer is either the oxide layer or the polymer layer; and
wherein the adhesive material or topsheet layer are applied to the uppermost layer before the uppermost layer contacts a processing roll,
wherein the oxide layer is an inorganic layer.

2. The method of claim 1, wherein the adhesive material includes a UV absorber.

3. The method of claim 1, wherein the adhesive material is a pressure sensitive adhesive.

4. The method of claim 1, wherein the steps of applying a polymeric material and/or applying an oxide-containing material are repeated sequentially numerous times to form a barrier assembly having numerous alternating polymer layers and/or oxide layers.

5. The method of claim 1, wherein the barrier assembly is flexible and transmissive to visible and infrared light.

6. The method of claim 1, further comprising:
forming a continuous roll of barrier assembly.

7. An optical device, comprising:
a barrier assembly made according to the method described in claim 1.

8. A photovoltaic module, comprising:
a barrier assembly made according to the method described in claim 1.

9. A method of forming a barrier assembly, comprising:
providing a substrate;
applying a polymeric material adjacent to the substrate to form a polymer layer;
applying an oxide-containing material adjacent to the polymer layer to form an oxide layer;
applying at least one of an adhesive material and a topsheet layer to and uppermost layer before the uppermost layer contacts any solid surface; and
wherein the uppermost surface is one of the oxide layer or the polymer layer, wherein the oxide layer is an inorganic layer.

10. The method of claim 9, wherein the adhesive material further includes a UV absorber.

11. The method of claim 9, wherein the adhesive material is a pressure sensitive adhesive.

12. The method of claim 9, wherein the steps of applying a polymeric material and/or applying an oxide-containing material are repeated sequentially numerous times to form a barrier assembly having numerous alternating polymer layers and/or oxide layers.

13. The method of claim 9, wherein the barrier assembly is flexible and light transmissive.

14. The method of claim 9, further comprising:
forming a continuous roll of barrier assembly.

15. The method of claim 9, wherein the topsheet includes an opaque portion.

16. An optical device, comprising:
a barrier assembly made according to the method described in claim 9.

17. A photovoltaic module, comprising:
a barrier assembly made according to the method described in claim 9.
